(19) United States
(12) Patent Application Publication
(10) Pub. No.: US 2009/0070038 A1
(43) Pub. Date: Mar. 12, 2009

(54) Navigation Device with Automatic Gps Precision Enhancement

(76) Inventors: Pieter Andreas Geelen, Amsterdam (NL); Serhiy Tkachenko, Amsterdam (NL); David Stelpstra, Amsterdam (NL); Kees Wesselius, Wormer (NL)

Correspondence Address: HARNESS, DICKEY & PIERCE, P.L.C., P.O. BOX 8910, RESTON, VA, 20195, US

(21) Appl. No.: 12/225,709

(22) PCT Filed: May 16, 2006
(86) PCT No.: PCT/NL2006/050116

§ 371 Date: Sep. 29, 2008

(51) Int. Cl. G01C 23/00; G01C 19/00; G01C 21/18; G01P 9/00; G01P 15/00; G01R 33/02

(52) U.S. Cl. 701/216; 701/220; 702/142; 73/504.18; 702/141; 324/244

(57) ABSTRACT

A navigation device is disclosed including a processor arranged to receive position information from a positioning device. The processor is also arranged to receive movement information from a movement detector and determine whether said device is standing still using said movement information. In at least one embodiment, if a standstill of the device is determined, the processor calculates an average position over time using information on consecutive positions received from the positioning system during a time period in which the device is standing still. The average position is used for navigation purposes, such as giving instructions to the user. By averaging during a standstill, a more accurate position can be determined which can be used to give better instructions.

### TECHNICAL FIELD

The present invention relates to a navigation device with automatic position precision enhancement. Also, the present invention relates to a method for providing navigation instructions.

### STATE OF THE ART

Prior art navigation devices based on GPS (Global Positioning System) are well known and are widely employed as in-car navigation systems. Such a GPS based navigation device relates to a computing device which in a functional connection to an external (or internal) GPS receiver is capable of determining its global position. Moreover, the computing device is capable of determining a route between start and destination addresses, which can be input by a user of the computing device. Typically, the computing device is enabled by software for computing a “best” or “optimum” route between the start and destination address locations from a map database. A “best” or “optimum” route is determined on the basis of predetermined criteria and need not necessarily be the fastest or shortest route.

The navigation device may typically be mounted on the dashboard of a vehicle, but may also be formed as part of an on-board computer of the vehicle or car radio. The navigation device may also be (part of) a hand-held system, such as a PDA or telephone.

By using positional information derived from the GPS receiver, the computing device can determine at regular intervals its position and can display the current position of the vehicle to the user. The navigation device may also comprise memory devices for storing map data and a display for displaying a selected portion of the map data.

Also, it can provide instructions how to navigate the determined route by appropriate navigation directions displayed on the display and/or generated as audible signals from a speaker (e.g. ‘turn left in 100 m’). Graphics depicting the actions to be accomplished (e.g. a left arrow indicating a left turn ahead) can be displayed in a status bar and also be superimposed upon the applicable junctions/turnings etc. in the map itself.

It is known to enable in-car navigation systems to allow the driver, whilst driving in a car along a route calculated by the navigation system, to initiate a route re-calculation. This is useful where the vehicle is faced with construction work or heavy congestion.

It is also known to enable a user to choose the kind of route calculation algorithm deployed by the navigation device, selecting for example from a ‘Normal’ mode and a ‘Fast’ mode (which calculates the route in the shortest time, but does not explore as many alternative routes as the Normal mode).

It is also known to allow a route to be calculated with user defined criteria; for example, the user may prefer a scenic route to be calculated by the device. The device software would then calculate various routes and weigh more favourably those that include along their route the highest number of points of interest (known as POs) tagged as being for example of scenic beauty.

Present GPS receivers are able to determine a global position with a limited accuracy. A GPS receiver typically receives position information every second with an error of about 10-20 meter, or even bigger when the device is in urban areas with many or high buildings, or rural areas with mountains, both hiding satellites. This error constitutes of a systematic static error component (due to weather and atmospheric conditions) and a varying error component (due to communication system noise). Due to the varying error component, a GPS receiver will find himself at changing positions every second. These inaccurate measurements of a GPS receiver will have direct consequences for the accuracy of a navigation device using such a GPS receiver.

### SHORT DESCRIPTION

So, it is desirable to provide a navigation device with an improved accuracy.

Therefore, according to an aspect of the claimed invention, there is provided a navigation device comprising a processor arranged to receive position information from a positioning device. The processor is further arranged to:

receive movement information from a movement detector;

determine whether the navigation device is standing still using the movement information, and if a standstill of the device is determined:

calculate an average position over time using information on consecutive positions received from the positioning device during a time period in which the device is standing still, and

use the average position for navigation purposes.

By averaging the consecutively received positions, the processor can improve the accuracy of the position of the navigation device.

In an embodiment, the processor is arranged to switch off all or some of the functionality of the navigation device once a standstill of the navigation device is determined. This will result in a power saving for the navigation device.

The movement information may comprise speed information produced by a vehicle speed measurement device. Such a speed sensor may already be present in a car, so that no additional component is needed to conclude whether a car is standing still.

The movement information may as well comprise data produced by a gyroscope, or an accelerometer, or a camera, or by a magnetometer. All these devices can be used to determine whether a device, and thus a vehicle carrying such a device, is standing still or not.

The invention also relates to a vehicle, such as a car, a bike, a boat or an airplane, comprising a navigation device as described above.

In another aspect of the invention, there is provided a method for providing navigation directions using a navigation device, the method comprising:
receive movement information from a movement detector;
determine whether the navigation device is standing still using the movement information, and if a standstill of the navigation device is determined:
   calculate an average position over time using information on consecutive positions received from said positioning device during a time period in which the device is standing still, and
use said average position for navigation purposes.

The method may also comprise a switch off all or some of the functionality of the navigation device once a standstill of the navigation device is determined.

In another aspect, there is provided a computer program, when loaded on a computer arrangement, giving the computer arrangement the ability to perform the method described above.

Finally, there is provided a data carrier, comprising the computer program mentioned above.

### SHORT DESCRIPTION OF THE DRAWINGS

Embodiments of the invention will now be described, by way of example only, with reference to the accompanying schematic drawings in which corresponding reference symbols indicate corresponding parts, and in which:

FIG. 1 schematically depicts a schematic block diagram of a navigation device according to an embodiment,

FIG. 2 schematically depicts a schematic view of a navigation device,

FIG. 3 shows a car comprising the navigation device according to an embodiment;

FIG. 4 shows a flow chart of a method according to an embodiment.

### DETAILED DESCRIPTION

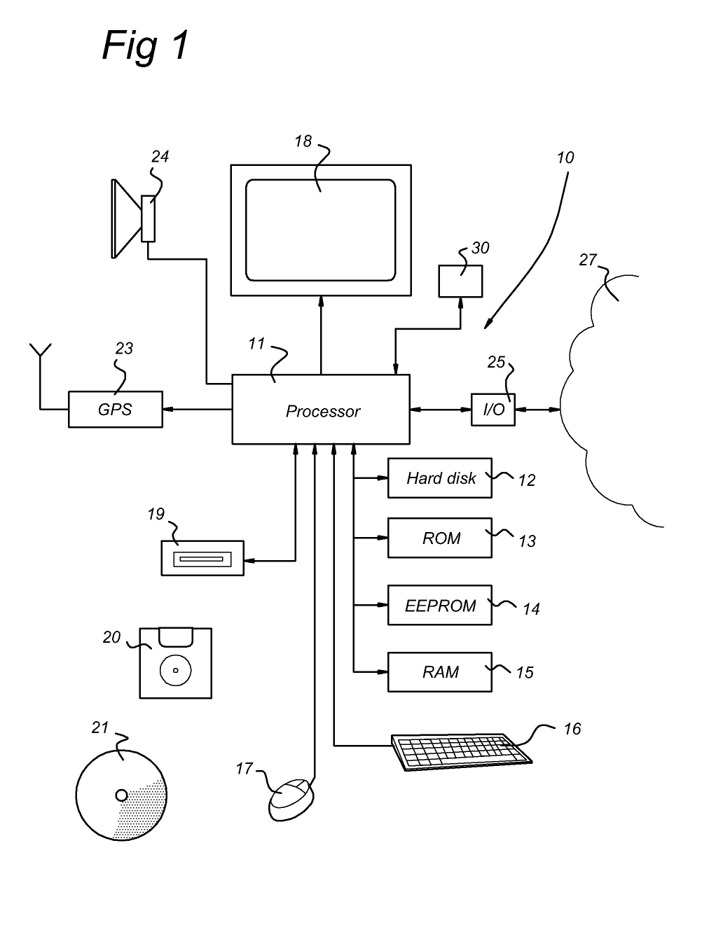

FIG. 1 shows a schematic block diagram of an embodiment of a navigation device 10, comprising a processor unit 11 for performing arithmetical operations. The processor unit 11 is arranged to communicate with memory units that store instructions and data, such as a hard disk 12, a Read Only Memory (ROM) 13, Electrically Erasable Programmable Read Only Memory (EEPROM) 14 and a Random Access Memory (RAM) 15. The memory units may comprise map data. This map data may be two dimensional map data (latitude and longitude), but may also comprise a third dimension (height). The map data may further comprise additional information such as information about petrol/gas stations, points of interest. The map data may also comprise information about the shape of buildings and objects along the road.

The processor unit 11 may also be arranged to communicate with one or more input devices, such as a keyboard 16 and a mouse 17. The keyboard 16 may for instance be a virtual keyboard, provided on a display 18, being a touch screen. The processor unit 11 may further be arranged to communicate with one or more output devices, such as a display 18, a speaker 24 and one or more reading units 19 to read for instance floppy disks 20 or CD ROM's 21. The display 18 could be a conventional computer display (e.g. LCD) or could be a projection type display, such as the head up type display used to project instrumentation data onto a car windscreen or windshield. The display 18 may also be a display arranged to function as a touch screen, which allows the user to input instructions and/or information by touching the display 18 with his finger.

The speaker 24 may be formed as part of the navigation device 10. In case the navigation device 10 is used as an in-car navigation device, the navigation device 10 may use speakers of the car radio, the board computer and the like.

The processor unit 11 may further be arranged to communicate with a positioning device 23, such as a GPS receiver, that provides information about the position of the navigation device 10. According to this embodiment, the positioning device 23 is a GPS based positioning device 23. However, it will be understood that the navigation device 10 may implement any kind of positioning sensing technology and is not limited to GPS. It can hence be implemented using other kinds of GNSS (global navigation satellite system) such as the European Galileo system. Equally, it is not limited to satellite based location/velocity systems but can equally be deployed using ground-based beacons or any other kind of system that enables the device to determine its geographical location.

However, it should be understood that there may be provided more and/or other memory units, input devices and read devices known to persons skilled in the art. Moreover, one or more of them may be physically located remote from the processor unit 11, if required. The processor unit 11 is shown as one box, however, it may comprise several processing units functioning in parallel or controlled by one main processor that may be located remote from one another, as is known to persons skilled in the art.

The navigation device 10 is shown as a computer system, but can be any signal processing system with analog and/or digital and/or software technology arranged to perform the functions discussed here. It will be understood that although the navigation device 10 is shown in FIG. 1 as a plurality of components, the navigation device 10 may be formed as a single device.

The navigation device 10 may use navigation software, such as navigation software from TomTom B.V. called Navigator. Navigator software may run on a touch screen (i.e. stylus controlled) Pocket PC powered PDA device, such as the Compaq iPaq, as well as devices that have an integral GPS receiver 23. The combined PDA and GPS receiver system is designed to be used as an in-vehicle navigation system. The embodiments may also be implemented in any other arrangement of navigation device 10, such as one with an integral GPS receiver/computer/display, or a device designed for non-vehicle use (e.g. for walkers) or vehicles other than cars (e.g. aircraft).

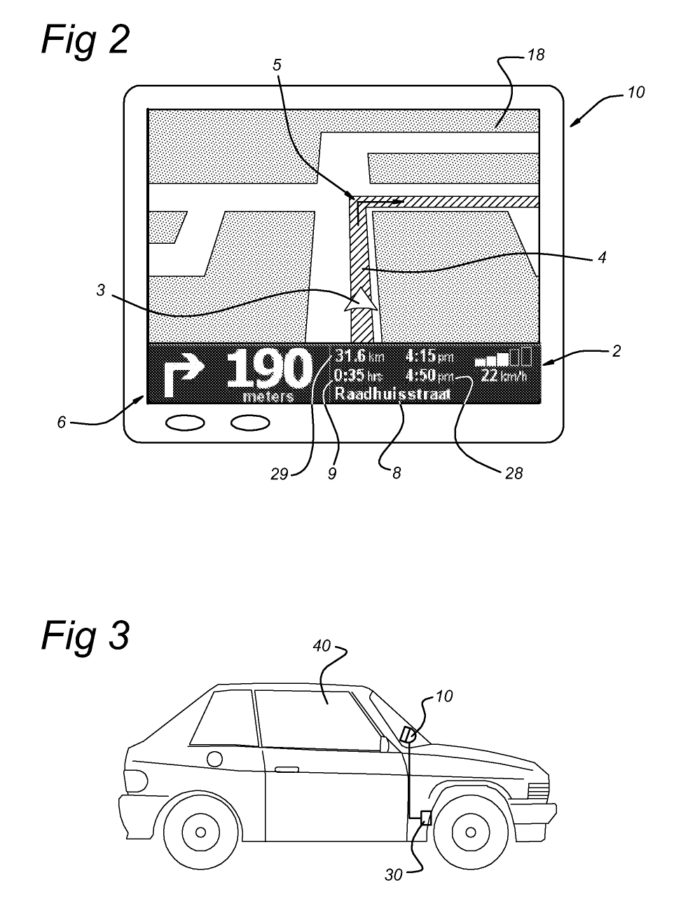

FIG. 2 depicts an example of a functioning display 18 of the navigation device 10 as described above.

Navigator software, when running on the navigation device 10, causes a navigation device 10 to display a normal navigation mode screen at the display 18, as shown in FIG. 2. This view may provide driving instructions using a combination of text, symbols, voice guidance and a moving map. Key user interface elements are the following: a 3-D map occupies most of the screen. It is noted that the map may also be shown as a 2-D map.

The map shows the position of the navigation device 10 and its immediate surroundings, rotated in such a way that the direction in which the navigation device 10 is moving is always “up”. Running across the bottom quarter of the screen may be a status bar 2. The current location of the navigation device 10 (as the navigation device 10 itself determines using conventional GPS location finding) and its orientation (as inferred from its direction of travel) is depicted by a position arrow 3. A route 4 calculated by the device (using route calculation algorithms stored in memory devices 11, 12, 13, 14, 15 as applied to map data stored in a map database in memory devices 11, 12, 13, 14, 15) is shown as darkened path. On the route 4, all major actions (e.g. turning corners, crossroads, roundabouts etc.) are schematically depicted by arrows 5 overlaying the route 4. The status bar 2 also includes at its left hand side a schematic icon depicting the next action 6 (here, a right turn). The status bar 2 also shows the distance to the next action (i.e. the right turn—here the distance is 190 meters) as extracted from a database of the entire route calculated by the device (i.e. a list of all roads and related actions defining the route to be taken). Status bar 2 also shows the name of the current road 8, the estimated time before arrival 9 (here 35 minutes), the actual estimated arrival time 28 (4.50 pm) and the distance to the destination 29 (31.6 km). The status bar 2 may further show additional information, such as GPS signal strength in a mobile-phone style signal strength indicator.

As already mentioned above, the navigation device 10 may comprise input devices, such as a touch screen, that allows the users to call up a navigation menu (not shown). From this menu, other navigation functions can be initiated or controlled. Allowing navigation functions to be selected from a menu screen that is itself very readily called up (e.g. one step away from the map display to the menu screen) greatly simplifies the user interaction and makes it faster and easier. The navigation menu includes the option for the user to input a destination.

The actual physical structure of the navigation device 10 itself may be fundamentally no different from any conventional handheld computer, other than the integral GPS receiver 23 or a GPS data feed from an external GPS receiver. Hence, memory devices 12, 13, 14, 15 store the route calculation algorithms, map database and user interface software; a processor unit 12 interprets and processes user input (e.g. using a touch screen to input the start and destination addresses and all other control inputs) and deploys the route calculation algorithms to calculate the optimal route. ‘Optimal’ may refer to criteria such as shortest time or shortest distance, or some other user-related factors.

More specifically, the user inputs his required destination into the navigation software running on the navigation device 10, using the input devices provided, such as a touch screen 18, keyboard 16 etc. The user then selects the manner in which a travel route is calculated: various modes are offered, such as a ‘fast’ mode that calculates the route very rapidly, but the route might not be the shortest; a ‘full’ mode that looks at all possible routes and locates the shortest, but takes longer to calculate etc. Other options are possible, with a user defining a route that is scenic—e.g. passes the most POI (points of interest) marked as views of outstanding beauty, or passes the most POIs of possible interest to children or uses the fewest junctions etc.

The navigation device 10 may further comprise an input-output device 25 that allows the navigation device 10 to communicate with remote systems, such as other navigation devices 10, personal computers, servers etc., via network 27. The network 27 may be any type of network 27, such as a LAN, WAN, Blue tooth, internet intranet and the like. The communication may be wired or wireless. A wireless communication link may for instance use RF-signals (radio frequency) and a RF-network.

Roads themselves are described in the map database that is part of navigation software (or is otherwise accessed by it) running on the navigation device 10 as lines—i.e. vectors (e.g. start point, end point, direction for a road, with an entire road being made up of many hundreds of such sections, each uniquely defined by start point/end point direction parameters). A map is then a set of such road vectors, plus points of interest (POIs), plus road names, plus other geographic features like park boundaries, river boundaries etc, all of which are defined in terms of vectors. All map features (e.g. road vectors, POIs etc.) are defined in a co-ordinate system that corresponds or relates to the GPS co-ordinate system, enabling a device's position as determined through a GPS system to be located onto the relevant road shown in a map.

Route calculation uses complex algorithms that are part of the navigation software. The algorithms are applied to score large numbers of potential different routes. The navigation software then evaluates them against the user defined criteria (or device defaults), such as a full mode scan, with scenic route, past museums, and no speed camera. The route which best meets the defined criteria is then calculated by the processor unit 11 and then stored in a database in the memory devices 12, 13, 14, 15 as a sequence of vectors, road names and actions to be done at vector end-points (e.g. corresponding to pre-determined distances along each road of the route, such as after 100 meters, turn left into street x).

Present navigation devices use for example the GPS satellites for determining the position of the devices. Due to noise in such positioning systems, a navigation device has a limited accuracy.

FIG. 1 shows an embodiment of the invention, in which the processor 11 of the navigation device 10 is arranged to receive movement information from a special movement detector 30. According to the invention, the processor 11 is arranged to determine whether the navigation device 11 (and thus the vehicle it is fixed to) is standing still using the movement information, and if a standstill of the device 10 is determined calculate an average position over time using information on consecutive positions received from the positioning device 23, such as a GPS receiver 23, during a time period in which the device is standing still, and use said average position for navigation purposes. It is noted that an average can already be calculated using only two positions. It is not necessary to use the whole time period in order to improve the accuracy.

If for example a GPS receiver 23 is used for determining the position of the navigation device 10, the processor 11 receives position information with an accuracy of about 10 meter. The processor 11 is arranged to receive movement information from the movement detector 30. Movement information may comprise speed values of a car but it may also comprise orientation values of a gyroscope arranged in or on the navigation device 10. The processor 11 is arranged to use this movement information in order to determine whether the navigation device is standing still. The movement values (or differences in movement values in case of the gyroscope) may for example be compared with a threshold below which it can be concluded that no movement is present. If it is determined by the processor 11 that the device 10 is standing still, the processor 11 will start a procedure to enhance the accuracy of the present position. During a period in which the navigation device 10 is standing still, the processor 11 will receive several position values over time from the GPS receiver 23. the processor 11 will then calculate an average position over time. This average position is usually more accurate than one particular measured position determined by the GPS system. This more accurate position is then used by the processor 11 for navigation purposes. The more accurate position can for example be used to correct the last used position. The more accurate position can for example be used for updating the map on the screen 18 or for recalculating the route. This may particularly be relevant when for example a car equipped with such a navigation device holds at a crossing. In this case, known navigation devices may be in doubt of which road the car is on. When making the wrong assumption, the known navigation devices will navigate a car into the wrong direction. The device according to the invention has an improved accuracy of about 4-6 meter, depending on the averaging time. As will be clear to the skilled reader, the longer the navigation device is standing still, the longer the averaging time, the more positions are used to calculate the average, the more precise the calculated position will be. It is noted that certain outliers (i.e. obvious measurement errors) may be filtered out and are preferably not used in the calculation of the average position.

In a second main embodiment, the processor 11 is arranged to enter a sleep mode once a stand still is determined. In the sleep mode the processor may switch off all or some of the functionality of the navigation device 10 except for the reception of movement information coming from the movement detector 30. In the sleep mode, the processing frequency of the processor 11 may be turned low, so that less energy is spent. It may also be possible that the GPS receiver 23 is not turned off during the sleep mode but continues to measure its position and that the processor 11 continues the averaging procedure as described above. The frequency of the GPS measurements may be lowered during sleep mode to save power. The processor 11 may temporarily wake up on every received GPS position from the GPS receiver, processes this data and goes back to sleep.

If during sleep mode the processor 11 receives movement values that exceed a predetermined threshold, the processor 11 will switch back to a normal navigation mode. In the normal navigation mode, the navigation device 10 will display information on the screen 18 and/or it will give navigation messages to the user by way of sounds.

The movement detector 30 may be arranged inside a housing of the navigation device 11 or it may be external from the device 11. In any case, the movement detector 30 is arranged to communicate with the processor 11 of the navigation device 10. Communication between the processor 11 and the movement detector 30 may be either wired or wireless using BlueTooth, WiFi, infrared, etc. The movement detector 30 may for example comprise a speed sensor 30, a gyroscope 30, an accelerometer 30, or it may comprise combinations of these sensors. The speed sensor 30 may be a wheel speed detector of a vehicle arranged to measure the speed of the vehicle. In this case it is assumed that the navigation device and the vehicle have the same velocity. The gyroscope 30 is a device arranged to very accurately detect changes in orientation of the navigation device 10. The accelerometer 30 is particularly useful for detecting accelerations and/or changes in direction of the navigation device 10. The movement detector 30 may as well comprise a camera 30 which in conjunction with the processor 11 is arranged to detect movement using pattern comparing software as will be known to the skilled person. With this pattern comparing software, the processor 11 is able to determine whether the navigation device 10 is standing still. In yet another embodiment, the movement detector 30 comprises a magnetometer. The magnetometer is arranged to measure changes of magnetic field line on the ground, and does not need any other external information to detect motion.

Contrary to a GPS device, the movement detectors 23 described above do not need input from an external noisy system, such as the GPS satellites or EGNOS, Galileo. This means that they can be used to determine a standstill of for example a car so that the processor 11 can start averaging in order to enhance the accuracy of the position.

The invention also relates to a vehicle 40, such as a car, comprising the navigation device 10 described above, see FIG. 3. In an embodiment, the car 40 comprises a speed sensor 30 arranged to measure the speed of the car 40

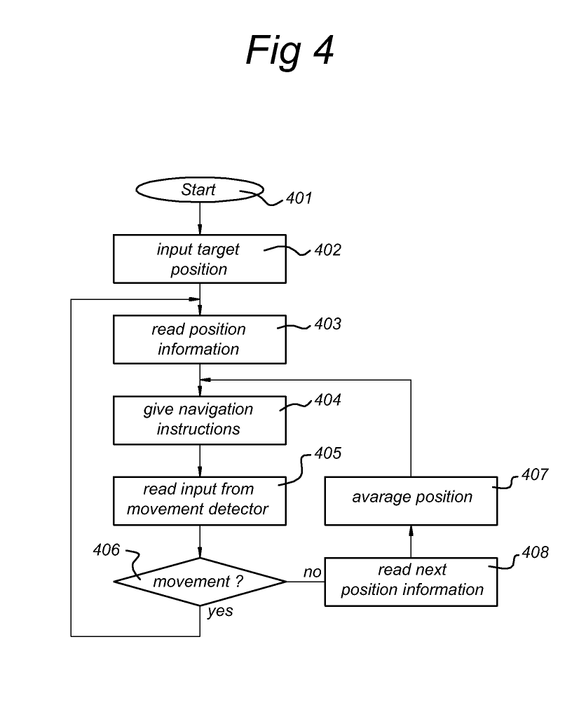

FIG. 4 shows a flow chart indicating an example of the method according to an embodiment of the invention. The method starts at step 401 wherein for example the navigation device 10 is turned ON by a user. Next, in a step 402, the device 10 receives a target position form the user. In a step 403, the device 10 will read position information form the GPS receiver 23. This position information is used in a next step 404 wherein all kinds of navigation functions may be performed, such as giving instructions to the user or display part of the recommended route. Then, in a step 405, the processor 11 reads its input from the movement detector 30. If a movement is detected, see test 406, the method goes to step 403 and the device 10 will receive the next position information. If however in test 406 it is concluded that the device 10 is not moving, a step 407 follows in which the device 10 will receive the next position information from the GPS receiver 23. Because of noise in the GPS system, this next position information will differ slightly from the previous position information, even if the device is standing still. The next position information is used, see step 408, together with the previous position information to calculate an average position. Most of the time, this average position is more accurate than only one single position determined by the GPS system. The average position is used for step 404 in which the device gives navigation information to the user.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein. It will be understood by a skilled person that all software components may also be formed as hardware components.

The descriptions above are intended to be illustrative, not limiting. Thus, it will be apparent to one skilled in the art that modifications may be made to the invention as described without departing from the scope of the claims set out below.

1. Navigation device, comprising:
a processor arranged to receive position information from a positioning device, said processor further being arranged to
receive movement information from a movement detector, and
determine whether said navigation device is standing still using said received movement information, and if a standstill of the navigation device is determined,
to
calculate an average position over time using information on consecutive positions received from said positioning device during a time period in which the navigation device is standing still, and
use said calculated average position for navigation purposes.

2. Navigation device according to claim 1, wherein said processor is arranged to switch off all or some of the functionality of the navigation device once a standstill of the navigation device is determined.

3. Navigation device according to claim 1, wherein said movement information includes speed information produced by a vehicle speed measurement device.

4. Navigation device according to claim 1, wherein said movement information includes data produced by a gyroscope.

5. Navigation device according to claim 1, wherein said movement information includes data produced by an accelerometer.

6. Navigation device according to claim 1, wherein said movement information includes data produced by a camera.

7. Navigation device according to claim 1, wherein said movement information includes data produced by a magnetometer.

8. Vehicle, comprising a navigation device according to claim 1.

9. Method for providing navigation directions using a navigation device, the method comprising:
receiving movement information from a movement detector; and
determining whether said navigation device is standing still using said movement information, and if a standstill of the navigation device is determined,
calculating an average position over time using information on consecutive positions received from an positioning device during a time period in which the navigation device is standing still, and
using said calculated average position for navigation purposes.

10. Method according to claim 9, the method comprising: switching off all or some of the functionality of the navigation device once a standstill of the navigation device is determined.

11. Computer program, when loaded on a computer arrangement, giving the computer arrangement the ability to perform the method of claim 9.

12. Data carrier, comprising a computer program according to claim 11.

13. Navigation device according to claim 2, wherein said movement information includes speed information produced by a vehicle speed measurement device.

14. Navigation device according to claim 2, wherein said movement information includes data produced by a gyroscope.

15. Navigation device according to claim 2, wherein said movement information includes data produced by an accelerometer.

16. Navigation device according to claim 2, wherein said movement information includes data produced by a camera.

17. Navigation device according to claim 2, wherein said movement information includes data produced by a magnetometer.

18. Vehicle, comprising a navigation device according to claim 2.

19. Computer program, when loaded on a computer arrangement, giving the computer arrangement the ability to perform the method of claim 10.

20. Data carrier, comprising a computer program according to claim 19.
